(19) United States
(12) Patent Application Publication
(10) Pub. No.: US 2012/0026690 A1
(43) Pub. Date: Feb. 2, 2012

(54) HEAT EXCHANGE MEDIUM AND ELECTRIC STORAGE DEVICE

(76) Inventors: Takashi Murata, Aichi-ken (JP); Takaaki Kano, Tokyo-to (JP); Shingo Uemura, Tokyo-to (JP); Koji Inada, Chiba-ken (JP); Tatsuya Matsuda, Aichi-ken (JP)

(21) Appl. No.: 13/258,697

(22) PCT Filed: Apr. 8, 2010
(86) PCT No.: PCT/IB2010/000759

§ 371 Date: Sep. 22, 2011

(30) Foreign Application Priority Data
Apr. 9, 2009 (JP) 2009-095087

(51) Int. Cl. H05K 7/20; F28D 15/00

(52) U.S. Cl. 361/696; 165/104.33

(57) ABSTRACT

A liquid heat exchange medium (40) is provided in a case (20) together with an electric storage element (11) to exchange heat with the electric storage element. The heat exchange medium is an ester compound of a fatty acid with a carbon number of 6 to 8 and 2-ethyl hexanol. The heat exchange medium contains 90 or more volume % of 2-ethylhexyl caprylate.

Selected Drawing: FIG. 1

### BACKGROUND OF THE INVENTION

1. Field of the Invention

The invention relates to a heat exchange medium for exchanging heat with an electric storage element, and an electric storage device employing this heat exchange medium.

2. Description of the Related Art

A secondary battery may generate heat when being charged or discharged, and properties of the secondary battery may deteriorate as a result of the increase in temperature. Approaches for holding a coolant (liquid) in contact with a secondary battery to minimize temperature increases in the secondary battery are described in, for example, Japanese Patent Application Publication No. 2001-060466 (JP-A-2001-060466) and Japanese Patent Application Publication No. 2008-16346 (JP-A-2008-16346).

In the assembled battery described in JP-A-2001-060466, a case for accommodating the assembled battery is provided with an inlet and an outlet. Coolant is supplied into the case via the inlet, and discharged from the case via the outlet. An insulating oil or a liquid paraffin may be used as the coolant.

Further, in an accommodation device described in JP-A-2008-16346, a cooling liquid is stored together with a secondary battery inside a battery accommodation chamber. Ethylene glycol is used as the cooling liquid.

In a structure in which a liquid is held in contact with a secondary battery, high heat conductivity, the presence of electric insulation properties, a remote possibility of deteriorating the secondary battery, and the like may be mentioned as the performances required of the liquid. It should be noted herein that the liquid described in JP-A-2001-060466 or JP-A-2008-16346 may exhibit the aforementioned performances insufficiently.

### SUMMARY OF THE INVENTION

The invention provides a heat exchange medium that is excellent in fluidity and insulation properties, and an electric storage device employing this heat exchange medium.

A heat exchange medium according to a first aspect of the invention is a liquid heat exchange medium that is provided in a case together with an electric storage element to exchange heat with the electric storage element. The heat exchange medium is an ester compound of a fatty acid with a carbon number of 6 to 8 and 2-ethyl hexanol, and contains 90 or more volume % of 2-ethylhexyl caprylate. More specifically, the heat exchange medium may be composed of 2-ethylhexyl caprylate alone or a mixture of 2-ethylhexyl caprylate and an ester compound of a fatty acid other than caprylic acid (with a carbon number of 6 to 8) and 2-ethyl hexanol.

The heat exchange medium according to the above aspect of the invention may not contain sulfur constituents. Thus, corrosion of the electric storage element and the like clue to sulfur constituents may be avoided.

An electric storage device according to a second aspect of the invention includes the heat exchange medium according to the foregoing first aspect of the invention.

The electric storage device according to the above aspect of the invention may further include a fan disposed in the case to circulate the heat exchange medium. By circulating the heat exchange medium disposed in the case, the heat exchange medium is caused to flow efficiently with the aid of a driving force of the fan.

In the electric storage device according to the above aspect of the invention, the fan may circulate the heat exchange medium to the electric storage element with a laminar flow state. If the fan is driven to generate a laminar flow of the heat exchange medium around the electric storage element, partial dispersion of the temperature within the electric storage element may be minimized.

In the electric storage device according to the above aspect of the invention, the fan may have a rotary shaft and a plurality of blades disposed on an outer peripheral surface of the rotary shaft. The fan may be disposed such that the rotary shaft extends in a direction that is substantially parallel to the electric storage element. The length of the plurality of blades may be approximately equal to the length of the electric storage element in a rotational direction of the rotary shaft of the fan.

The electric storage device according to the above aspect of the invention may be mounted on a vehicle.

According to the invention, the insulating properties and fluidity of the liquid heat exchange medium that exchanges heat with the electric storage element may be enhanced by using an ester compound of a fatty acid with a carbon number of 6 to 8 and 2-ethyl hexanol (containing 90 or more volume % of 2-ethylhexyl caprylate) as the heat exchange medium. The safety in handling the electric storage device may be enhanced by improving the insulating properties of the heat exchange medium. Further, the temperature of the electric storage element may be efficiently adjusted with the aid of the heat exchange medium by enhancing the fluidity thereof.

### BRIEF DESCRIPTION OF THE DRAWINGS

The foregoing and/or further objects, features and advantages of the invention will become more apparent from the following description of an example embodiment of the invention with reference to the accompanying drawings, in which like numerals are used to represent like elements and wherein:

FIG. 1 is an exploded perspective view showing the structure of a battery pack according to the first embodiment of the invention;

FIG. 2 shows the internal sturcture of part of the battery pack according to the first embodiment of the invention;

FIG. 3 shows the main flow of a heat exchange medium in the battery pack according to the first embodiment of the invention;

FIG. 4 shows the flow directions of the heat exchange medium in the battery pack according to the first embodiment of the invention;

FIG. 5 shows a relationship between temperature and kinematic viscosity in the heat exchange medium according to the first embodiment of the invention; and

FIG. 6 shows a relationship between ambient temperature and temperature dispersion in a battery module according to the first embodiment of the invention.

### DETAILED DESCRIPTION OF EMBODIMENT

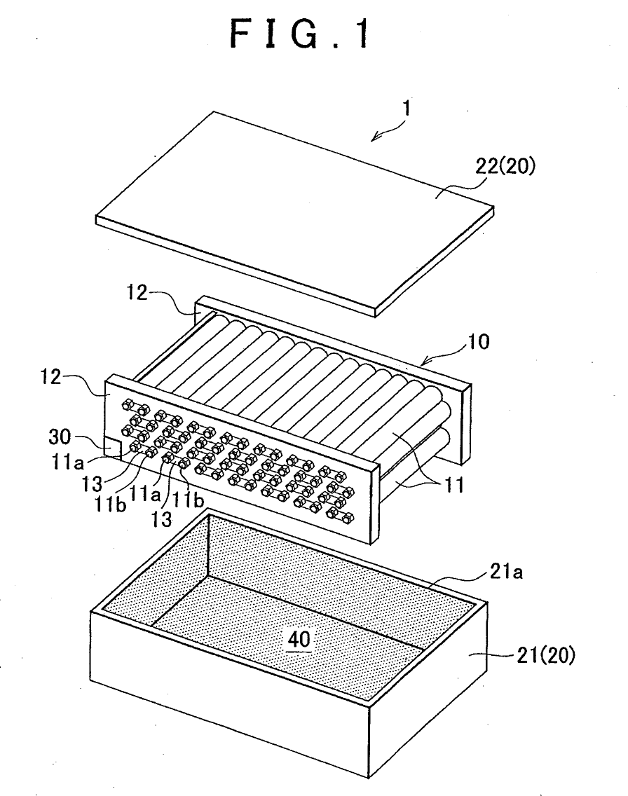

The structure of a battery pack (an electric storage device) according to the first embodiment of the invention will be described using FIG. 1. FIG. 1 is an exploded perspective view showing the structure of the battery pack according to this embodiment of the invention.

A battery pack 1 (an electric storage device) according to this embodiment of the invention is mounted on a vehicle. The vehicle may be a hybrid vehicle or an electric vehicle. The hybrid vehicle may be further equipped with, in addition to the battery pack 1, another power source that outputs energy used to cause the vehicle to run, such as an internal combustion engine or a fuel cell. Alternatively, the electric vehicle is a vehicle that runs using only the output of the battery pack 1. The battery pack 1 according to this embodiment of the invention outputs energy used to cause the vehicle to run through discharge, and is charged with kinetic energy generated during the braking of the vehicle as a regenerative electric power. It should be noted that the battery pack 1 may also be charged by supplying an electric power thereto from outside the vehicle.

The battery pack 1 includes a battery module 10, a pack case 20, and a circulation unit 30. The pack case 20 includes an accommodation member 21 that forms a space for accommodating the battery module 10 and the circulation unit 30, and a lid member 22 that closes an opening portion 21a of the accommodation member 21. The lid member 22 is fixed to the accommodation member 21 by a fastening member such as a screw or the like or through welding. Thus, the interior of the pack case 20 is sealed.

The accommodation member 21 and the lid member 22 may be made from any material having sufficient heat conductivity, corrosion resistance, and the like, for example, a material with heat conductivity is equal to or higher than that of a later-described heat exchange medium 40 (an ester compound). More specifically, the accommodation member 21 and the lid member 22 can be made of a metal such as aluminum, iron, or the like. The outer wall surfaces of the accommodation member 21 and the lid member 22 are designed as flat surfaces in this embodiment of the invention, however the invention is not restricted to this configuration. More specifically, a plurality of heat radiating fins can be provided on at least one of the outer wall surfaces of the accommodation member 21 and the lid member 22. Thus, the heat radiation performance of the battery pack 1 may be improved via the heat radiating fins.

In addition to the battery module 10 and the circulation unit 30, the liquid heat exchange medium 40 for exchanging heat with the battery module 10 is accommodated inside the pack case 20. The constituents of the heat exchange medium 40 will be described later.

The heat exchange medium 40 is used to adjust the temperature of the battery module 10 (electric cells 11 (electric storage elements)). It should be noted herein that the amount of the heat exchange medium 40 accommodated inside the pack case 20 may be set as appropriate. More specifically, the liquid surface of the heat exchange medium 40 may be either in contact or out of contact with the lid member 22. The heat exchange medium 40 preferably maintains contact with the entire surface of the battery module 10.

Next, the structure of the battery module 10 will be described.

The battery module 10 is composed of a plurality of the electric cells (secondary batteries or electric storage elements) 11 that are electrically connected to one another in series. The plurality of the electric cells 11 are oriented parallel with one another inside the pack case 20. Nickel hydride batteries or lithium ion batteries may be employed as the secondary batteries. Further, electric double layer capacitors may also be employed instead of the secondary batteries. In addition, although cylindrical electric cells 11 are employed in this embodiment of the invention, electric cells formed in other shapes, such as rectangular electric cells or the like, can also be employed.

Each electric cell 11 includes a power generation element (not shown), and a battery case that accommodates the power generation element in a sealed state. The power generation element may be charged with an electric power and can discharge the electric power therefrom, and can be composed of, for example, electrode elements (a positive electrode element and a negative electrode element) and separators. The positive electrode element is obtained by forming a layer of a positive electrode active material on the surface of a collector plate, and the negative electrode element is obtained by forming a layer of a negative electrode active material on a surface of a collector plate.

A positive electrode terminal 11a and a negative electrode terminal 11b are respectively provided at opposite ends of the e electric cell 11. The positive electrode terminal 11a is electrically and mechanically connected to the positive electrode element of the power generation element, and the negative electrode terminal 11b is electrically and mechanically connected to the negative electrode element of the power generation element. The positive electrode terminal 11a of each electric cell 11 is electrically connected to the negative electrode terminal 11b of an adjacent electric cell 11 via a bus bar 13. Thus, the plurality of the electric cells 11 are electrically connected to one another in series.

Each end of each individual electric cell 11 is supported by a flat support member 12. The support members 12 are fixed to the pack case 20 (the accommodation member 21) by a fastening member (not shown) such as a screw or the like. Further, end surfaces (outer edge portions) of each support member 12 contact the bottom surface and lateral surfaces of the accommodation member 21.

Although two support members 12 are employed in this embodiment of the invention, they can be integrated with each other. Further, if rectangular electric cells 11 are employed, the plurality of the electric cells 11 can be arranged in a certain direction with spacers sandwiched therebetween respectively, and can be sandwiched at both ends thereof in the direction of arrangement by end plates.

Cables (not shown) for the positive electrode and the negative electrode are connected to specific ones (two) of the plurality of the electric cells 11. These cables are connected to devices disposed outside the pack case 20. These devices may be, for example, a DC/DC converter for raising the voltage of the battery module 10 and an inverter for converting a direct current and an alternating current into each other.

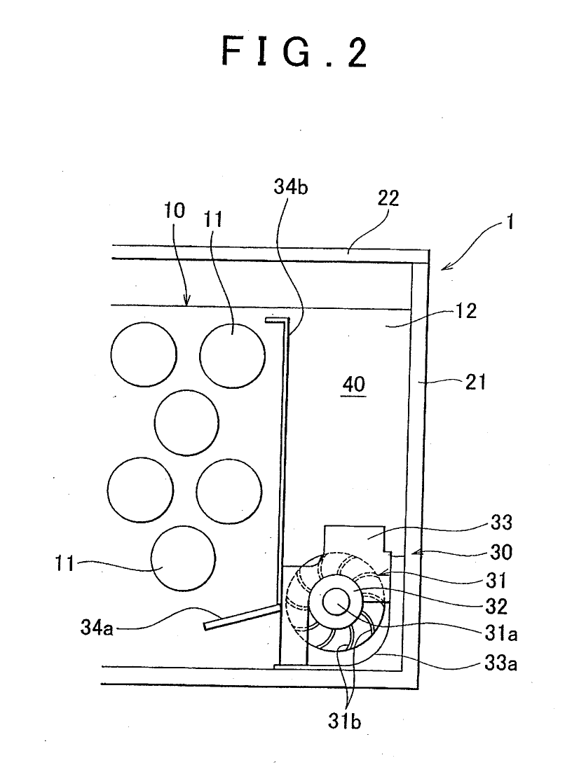

The circulation unit 30 is disposed at a corner portion of the battery module 10. Both ends of the circulation unit 30 are so disposed as to be located on the same plane as the pair of the support members 12. The structure of the circulation unit 30 will be described using FIG. 2. It should be noted herein that FIG. 2 is a partial schematic view of the structure of the interior of the battery pack 1.

The circulation unit 30 has a fan (a cross flow fan) 31, a pair of bearings 32 that rotatably support a rotary shaft 31a of the fan 31, and a support plate 33 that supports the bearing 32. The fan 31 has a plurality of blades 31b on the outer peripheral surface of the rotary shaft 31a. Further, the fan 31 is disposed such that an axis of rotation of the rotary shaft 31a extends substantially parallel to the electric cells 11. The plurality of the blades 31b are equidistantly disposed in a circumferential direction of the rotary shaft 31a, and are each formed in a curved shape. The length of the respective blades 31b in the direction of the rotary shaft of the fan 31 is approximately equal to the distance between the pair of the support members 12.

A motor (not shown) is connected to the rotary shaft 31a, and the fan 31 rotates by receiving a driving force from the motor. A region 33a of the support plate 33 is formed along an outer periphery of the fan 31 to allow the heat exchange medium 40 to move smoothly as the fan 31 rotates.

A first partition member 34a is connected to a second partition member 34b and both are disposed between the fan 31 and the battery module 10 (the electric cells 11). As shown in FIG. 2, the first partition member 34a is disposed between the lowest electric cell 11 of the battery module 10 and a bottom surface of the pack case 20 (the accommodation member 21). Further, the second partition member 34b extends in the direction of gravity (a vertical direction in FIG. 2) along the battery module 10, and a tip of the second partition member 34b is located at an upper portion of the battery module 10. The widths of the first partition member 34a and the second partition member 34b are each equal to the distance between the pair of the support members 12.

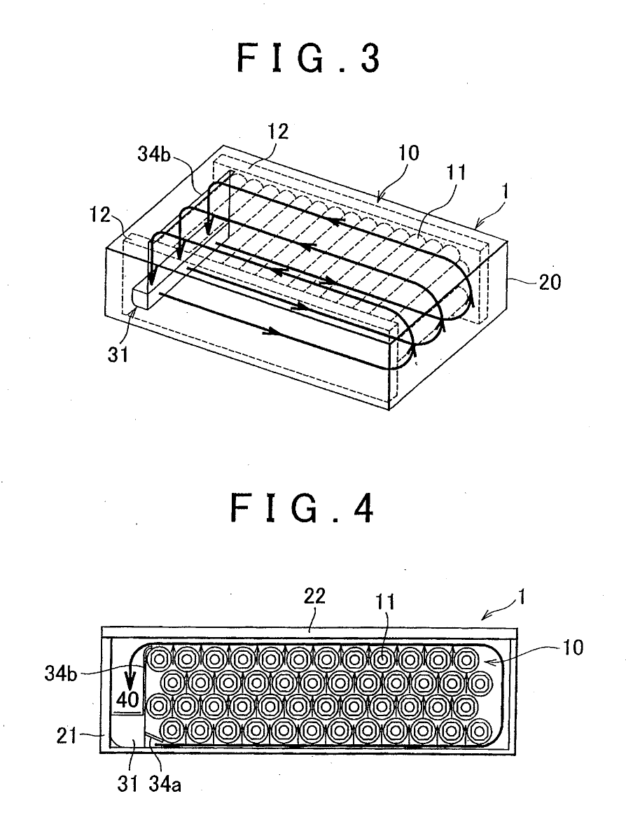

Next, the flow of the heat exchange medium 40 in the battery pack 1 when the fan 31 is driven, as described above, will be described using FIGS. 3 and 4.

When the fan 31 is rotated by the driving force of the motor, the heat exchange medium 40 is circulated by the fan 31. The heat exchange medium 40 circulated by the fan 31 passes a space between the first partition member 34a and the bottom surface of the accommodation member 21, and moves to the battery module 10 side. The plurality of the blades 31b of the fan 31 extends along the length of the rotary shaft 31a, and that the heat exchange medium 40 circulated by the fan 31 hence forms a laminar flow having the length of the blades 31b.

As indicated by arrows in FIG. 3, the heat exchange medium 40 circulated the fan 31 moves along the periphery of the battery module 10 and returns to the fan 31. The arrows in FIG. 3 indicate the main flow of the heat exchange medium 40, but the heat exchange medium 40 may flow in other directions as well. It should be noted that the first partition member 34a is omitted in FIG. 3.

In this embodiment of the invention, the distance (the shortest distance) between the battery module 10 (the outermost one of the electric cells 11) and an inner wall surface of the pack case 20 is longer than the distance (the shortest distance) between adjacent ones of the electric cells 11. By setting the distance in this manner, the heat exchange medium 40 sent out from the fan 31 can be moved along the periphery of the battery module 10. By causing the main flow of the heat exchange medium 40 around the battery module 10, secondary flow of the heat exchange medium 40 is also generated between adjacent electric cells 11 as well. More specifically, as shown in FIG. 4, the heat exchange medium 40 can be caused to circulate through spaces between adjacent ones of the electric cells 11 in a direction from a lower region of the battery module 10 to an upper region thereof.

The charging and discharging of the electric cells 11 may generate heat. However, by holding the heat exchange medium 40 in contact with the electric cells 11, heat is exchanged between the electric cells 11 and the heat exchange medium 40, and the heat of the electric cells 11 is transmitted to the heat exchange medium 40. The heated heat exchange medium 40 flows inside the pack case 20 as described above, and comes into contact with inner wall surfaces of the pack case 20, thereby allowing the heat to be transmitted to the pack case 20. The heat transmitted to the pack case 20 is then dissipated into the atmosphere. Thus, heat radiation (the cooling) of the battery pack 1 (the electric cells 11) can be carried out.

In contrast, when the heat exchange medium 40 is warmed, heat may be transmitted to the electric cells 11 through heat exchange between the warmed heat exchange medium 40 and the electric cells 11. Thus, the electric cells 11 can be warmed. The warming of the electric cells 11 is effective when the temperature of the electric cells 11 has excessively fallen due to an ambient temperature.

The heat exchange medium 40 can be directly or indirectly warmed in warming the heat exchange medium 40. As a method of directly warming the heat exchange medium 40, for example, it is possible to dispose a heater in the pack case 20 whereby the heater remains in contact with the heat exchange medium 40. Further, as a method of indirectly warming the heat exchange medium 40, for example, it is possible to warm the pack case 20 by means of a heater and warm the heat exchange medium 40 via the pack case 20.

In this embodiment of the invention, the heat exchange medium 40 sent out from the fan 31 comes into contact with the electric cells 11 in the laminar flow state. It should be noted herein that the width of a laminar flow of the heat exchange medium 40 is approximately equal to the length of the electric cells 11 in the longitudinal direction. Therefore, the heat exchange medium 40 exchanges heat with substantially entire regions of the electric cells 11. Thus, partial dispersion of the temperature in the electric cells 11 may be suppressed. Further, as shown in FIG. 4, heat exchange with all the electric cells 11 can be carried out by holding the heat exchange medium 40 in contact with all the electric cells 11 constituting the battery module 10. Thus, the dispersion of the temperature in the plurality of the electric cells 11 constituting the battery module 10 can be suppressed.

It should be noted that the circulation unit 30 is disposed within the pack case 20 in this embodiment of the invention. However, the circulation unit 30 may not be disposed. Further, although the cross-flow fan is employed as the fan 31, any fan having a structure that generates adequate force to circulate the heat exchange medium 40 may be employed. Furthermore, although the circulation unit 30 is disposed along the bottom surface of the pack case 20 in this embodiment of the invention, the invention is not limited to this configuration. That is, the circulation unit 30 may be located at any position as long as the heat exchange medium 40 is appropriately circulated around the battery module 10. For example, the circulation unit 30 may instead be disposed along an upper surface of the pack case 20.

Next, the concrete constituents of the heat exchange medium 40 will be described.

An ester compound of a fatty acid with a carbon number of 6 to 8 and 2-ethylhexanol is used as the heat exchange medium 40. The ester compound contains 90 or more volume % of 2-ethylhexyl caprylate. The heat exchange medium 40 may be composed of 2-ethylhexyl caprylate alone or contain 10 or less volume % of an ester compound with a fatty acid other than caprylic acid (with a carbon number of 6 to 8).

For example, caproic acid, enanthic acid, or caprylic acid can be mentioned as a fatty acid with a carbon number of 6 to 8 (the number of carbons of R¹ is 5 to 7). One of these fatty acids (caprylic acid) can be used alone, or two or more of these fatty acids (including caprylic acid) can be mixed and used.

It should be noted herein that the carbon number of the fatty acid is preferably equal to or larger than 6 to ensure appropriate insulative properties of the heat exchange medium (the ester compound) 40. Further, the carbon number of the fatty acid is preferably equal to or smaller than 8 to maintain appropriate fluidity of the heat exchange medium 40 in the pack case 20. The fluidity of the heat exchange medium 40 may be enhanced as the kinematic viscosity of the ester compound decreases. On the other hand, the heat exchange medium 40 can be endowed with excellent properties as to fluidity at low temperatures and electric insulating properties by using 2-ethylhexanol.

For example, 2-ethylhexyl caprylate or 2-ethylhexyl caproate may be mentioned as the aforementioned ester compound of the fatty acid with the carbon number of 6 to 8 and 2-ethylhexanol. One (2-ethylhexyl caprylate) of these ester compounds may be used alone, or two or more (2-ethylhexyl caprylate is contained) of these ester compounds may be mixed and used.

The ester compound used as the heat exchange medium 40 may be manufactured using various esterifying methods. For example, there is a method in which a fatty acid with a carbon number of 6 to 8 and 2-ethylhexanol are caused to react with each other under the presence of an acid or an alkali to be esterified. Further, it is also possible to obtain a transesterified produce by reacting a fatty acid with a carbon number of 6 to 8 and 2-ethylhexanol in the presence of an acid or an alkali.

If an ester compound is used, the Prandtl number at 20° C. is preferably 8 to 40000. Thus, the heat transfer coefficient of the heat exchange medium 40 may be increased, and the temperature of the battery module 10 may be efficiently adjusted using the heat exchange medium 40.

As described above, when an ester compound is used as the heat exchange medium 40, excellent insulating properties can be obtained. Thus, the ester compound may be suitably used for the battery module 10 that generates a high voltage. Further, even if 200 ppm or less of water is added to the ester compound, ester molecules surround water molecules. Therefore, changes in the volume resistivity of the ester compound are minimal.

In addition, if an ester compound is used, the heat exchange medium 40 is allowed not to contain sulfur constituents. For example, a catalyst that does not contain sulfur may be used to esterify a fatty acid with a carbon number of 6 to 8 and 2-ethylhexanol. Thus, the risk of the battery module 10 being partially corroded by sulfur may be avoided in comparison with a case where a mineral oil containing sulfur is used. For example, if the bus bar 13 and the electrode terminals 11a and 11b of each of the electric cells 11 are made of copper, the risk of these members being corroded by sulfur can be avoided.

Table 1 shown below shows the kinematic viscosity of the heat exchange medium 40 with respect to its temperature for example 1, in which 2-ethylhexyl caprylate is used alone as the heat exchange medium 40, and a comparative example that uses a mineral oil as the heat exchange medium 40. In particular, an automatic transmission fluid (ATF; Toyota Auto Fluid WS) is used as the mineral oil.

TABLE 1

| | | kinematic viscosity [mm²/s] | | | |
|---|---|---|---|---|---|
| | | (−30° C.) | (0° C.) | (40° C.) | (100° C.) |
| example 1 | 2-ethylhexyl | 32.64 | 8.164 | 2.841 | 1.174 |
| | caprylate | | | | |
| comparative | mineral oil | 2371.7 | 142.9 | 23.6 | 5.4 |
| example | | | | | |

Table 2 shows the volume resistivity of 2-ethylhexyl caprylate, mineral oil, and silicon oil.

TABLE 2

| | volume resistivity [Ω · cm] |
|---|---|
| 2-ethylhexyl caprylate | 5.4 × 10¹⁰ |
| mineral oil | 5.8 × 10¹⁰ |
| silicon oil | 5.0 × 10¹⁰ |

As shown in Table 2, 2-ethylhexyl caprylate is approximately equal in volume resistivity to mineral oil and silicon oil. Thus, 2-ethylhexyl caprylate may be suitably used as the heat exchange medium 40 that is in contact with the battery module 10 designed to generate a high voltage.

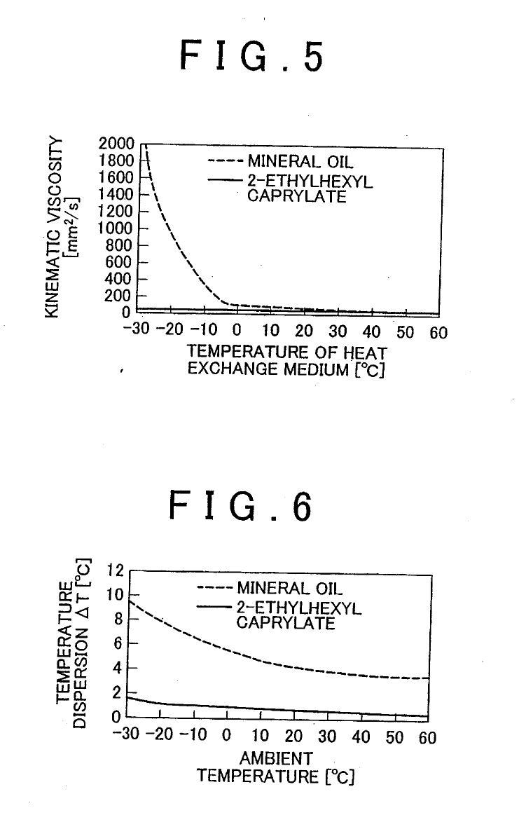

In contrast, FIG. 5 shows relationships between the temperature and kinematic viscosity of the heat exchange medium 40 when mineral oil and 2-ethylhexyl caprylate are used as the heat exchange medium 40 respectively.

As shown in FIG. 5, when 2-ethylhexyl caprylate is used, the kinematic viscosity of the heat exchange medium 40 is unlikely to change even when the temperature of the 2-ethylhexyl caprylate changes. On the other hand, the kinematic viscosity of mineral oil increases as its temperature falls below 0° C. Thus, if the battery pack 1 according to this embodiment of the invention is used in an environment below 0° C., 2-ethylhexyl caprylate is preferably used as the heat exchange medium 40.

FIG. 6 shows the relationships between the ambient temperature and a temperature dispersion in the plurality of the electric cells 11 of the battery module 10 when mineral oil and 2-ethylhexyl caprylate are used as the heat exchange medium 40, respectively. The temperature dispersion (ΔT) represents a difference in temperature between that one of the plurality of the electric cells 11 constituting the battery module 10 which is at the highest temperature and that one of the plurality of the electric cells 11 constituting the battery module 10 which is at the lowest temperature after the driving of the fan 31 in the battery pack 1 for a predetermined time. Further, the ambient temperature refers to the temperature around the battery pack 1.

As shown in FIG. 6, the temperature dispersion in the battery module 10 can be suppressed in the case where 2-ethylhexyl caprylate is used than in the case where mineral oil is used. The dispersion of performance deterioration in the plurality of the electric cells 11 is then be suppressed by suppressing the temperature dispersion. Thus, the plurality of the electric cells 11 that constitute the battery module 10 may be used in a well-balanced manner. As a result, the battery module 10 can be efficiently charged and discharged.

Further, in the case where 2-ethylhexyl caprylate is used as the heat exchange medium 40, even when an electrolytic solution of the electric cells 11 leaks to the heat exchange medium 40 and the concentration of the electrolytic solution becomes equal to or higher than 20 [vol %], the volume resistivity of this liquid can be made equal to or higher than 1.0×10⁵ Ω.cm. Furthermore, 2-ethylhexyl caprylate is not decomposed by the electrolytic solution of the electric cells 11 either. It should be noted that when the electric cells 11 generate excessive heat, a gas may be discharged from the electric cells 11 (the battery case) and the electrolytic solution of the power generation elements may leak together with this gas. For example, dimethyl carbonate (DMC) or ethyl methyl carbonate (EMC) is used as the electrolytic solution.

Thus, it is preferable to ensure the insulating properties of the heat exchange medium 40 even if the electrolytic solution leaks from the electric cells 11. As described above, when 2-ethylhexyl caprylate is used as the heat exchange medium 40, the volume resistivity of the heat exchange medium 40 can be restrained from falling drastically.

However, a resinous material or a rubber material may be used for the pack case 20 and a vehicle body on which the battery pack 1 is mounted. For example, acrylonitrile butadiene styrene (ABS), polybutylene terephthalate (PBT), polyamide 6 (PA6), or polyamide 66 (PA66) may be suitably used as the resinous material. Further, the rubber material is used, for example, to ensure sealability. Acrylonitrile butadiene rubber (NBR), Viton®, or polyurethane may be suitably used as the rubber material.

It should be noted herein that when 2-ethylhexyl caprylate is used as the heat exchange medium 40, Based on the following sentences, it seems to me that this should be rewritten as “the degree of change in the volume and weight of the above resinous material or rubber material may be minimized. More specifically, when the resinous material is soaked in the ester compound (2-ethylhexyl caprylate) at 70° C. for two weeks, the degree of change in the volume and weight of the resinous material was equal to or below 0.5%. Further, when the rubber material is soaked in the ester compound (2-ethylhexyl caprylate) at 70° C. for two weeks, the degree of change in volume and weight of the rubber material was equal to or below 20%. In this manner, when 2-ethylhexyl caprylate is used as the heat exchange medium 40, the battery pack 1 and the vehicle body in which the battery pack 1 is installed may be prevented from being adversely affected.

While the invention has been described with reference to the example embodiment thereof, it should be understood that the invention is not limited to the example embodiment or construction. To the contrary, the invention is intended to cover various modifications and equivalent arrangements. In addition, while the various elements of the example embodiment of the invention are shown in various combinations and configurations, which are exemplary, other combinations and configurations, including more, less or only a single element, are also within the spirit and scope of the invention.

1. A liquid heat exchange medium provided in a case together with an electric storage element to exchange heat with the electric storage element, wherein
the heat exchange medium is an ester compound of a fatty acid with a carbon number of 6 to 8 and 2-ethyl hexanol, and
the heat exchange medium contains 90 or more volume % of 2-ethylhexyl caprylate.

2. The heat exchange medium according to claim 1, wherein the heat exchange medium does not contain sulfur constituents.

3. An electric storage device equipped with the heat exchange medium according to claim 1.

4. The electric storage device according to claim 3, further comprising a fan disposed in the case to circulate the heat exchange medium.

5. The electric storage device according to claim 4, wherein the fan circulates the heat exchange medium to the electric storage element with a laminar flow state.

6. The electric storage device according to claim 5, wherein the fan comprises:
a rotary shaft; and
a plurality of blades disposed on an outer peripheral surface of the rotary shaft, wherein the fan is disposed such that the rotary shaft extends in a direction that is substantially parallel to the electric storage element, and
the length of the plurality of blades is approximately equal to the length of the electric storage element in a rotational direction of the rotary shaft of the fan.

7. The electric storage device according to claim 3, wherein the electric storage device is mounted on a vehicle.
